(19) United States
(12) Patent Application Publication
(10) Pub. No.: US 2026/0060147 A1
(43) Pub. Date: Feb. 26, 2026

(54) SEMICONDUCTOR PACKAGE COMPONENT AND METHOD OF MAKING THE SAME

(71) Applicant: Powertech Technology Inc., Hukou (TW)

(72) Inventor: Yi-Kai FU, Hukou (TW)

(73) Assignee: Powertech Technology Inc., Hukou (TW)

(21) Appl. No.: 19/306,341

(22) Filed: Aug. 21, 2025

(30) Foreign Application Priority Data
Aug. 23, 2024 (TW) 113131812

(51) Int. Cl. H01L 25/065; H01L 21/48; H01L 23/00; H01L 23/498; H01L 23/538; H01L 23/544

(52) U.S. Cl. CPC H01L 25/0655; H01L 21/4853; H01L 23/49816; H01L 23/5385; H01L 23/544; H01L 23/562; H01L 2223/54433; H01L 2223/54486

(57) ABSTRACT

A semiconductor package component which has an outer profile including an oblique package edge obliquely interconnecting between two adjacent side walls. The semiconductor package component includes a first redistribution layer (RDL) unit, a chip unit, a dummy die unit, an encapsulation layer, and a second RDL unit. The chip unit is disposed on the first RDL unit. The dummy die unit includes a dummy die that is disposed on the first RDL unit, and has a dummy die edge which extends in a direction parallel to the oblique package edge. A method for making the semiconductor package component is also disclosed.

### CROSS-REFERENCE TO RELATED APPLICATION

This application claims priority to Taiwanese Invention Patent Application No. 113131812, filed on Aug. 23, 2024, and incorporated by reference herein in its entirety.

### FIELD

The disclosure relates to a semiconductor package component, and more particularly to a semiconductor package component and a method of making the same.

### BACKGROUND

Semiconductor packaging is an important process in semiconductor fabrication. The exterior appearances of semiconductor package components, or the position or number of chips contained in the semiconductor package components vary according to the structural requirements or required performance characteristics of the semiconductor package components. In certain cases, specific requirements may cause the semiconductor package components to have an asymmetric or uneven distribution of chips so that chips may be located densely or loosely in some areas of the semiconductor package components. In some cases, this may result in finished semiconductor packaged components with asymmetrical (or irregular) shapes, and stress buildup may occur in certain areas due to the asymmetric or uneven chip distribution, thereby leading to problems such as warpage.

Referring to FIG. 1, in order to prevent the warpage problems due to the uneven chip distribution, a plurality of dummy dies 102 are disposed in a conventional semiconductor package component 100 in areas not occupied by the chips 101 so as to cooperate with the chips 101 to form a symmetric arrangement for alleviation of stress buildup due to uneven chip distribution and hence provide reinforcement for the conventional semiconductor package component 100.

However, adding dummy dies for reinforcement is only helpful for semiconductor package components that have a symmetrical shape. For the conventional semiconductor package component 100 as shown in FIG. 1 that is asymmetrical due to the presence of an oblique edge, although the dummy dies 102 disposed in a region inside the conventional semiconductor package 100 can provide a reinforcing effect, the structurally reinforcing effect of the dummy dies 102 is limited for a region of symmetrical shape near the oblique edge.

### SUMMARY

Therefore, an object of the disclosure is to provide a semiconductor package component and a method of making the semiconductor package component that can alleviate at least one of the drawbacks of the prior art.

According to a first aspect of the disclosure, the semiconductor package includes an oblique package edge, a first redistribution layer (RDL) unit, a chip unit, a dummy die unit, an encapsulation layer, and a second RDL unit. The oblique package edge obliquely interconnects between two sidewalls of a multisided periphery of the semiconductor package component. The chip unit is disposed on the first RDL unit. The dummy die unit includes at least one dummy die disposed on the first RDL unit, and having a dummy die edge which extends in a direction parallel to the oblique package edge. The encapsulation layer covers the first RDL unit, the chip unit, and the dummy die unit. The second RDL unit is formed on a top side of the encapsulation layer that is away from the first RDL unit, is electrically connected to the chip unit, and has a plurality of second RDL connector pads that are exposed on a top surface of the second RDL unit facing away from the top side of the encapsulation layer, and that allow electrical connection of the chip unit with an external power source.

According to another aspect of the disclosure, the method of making the semiconductor package component described above includes: a) forming the first RDL unit on a substrate; b) disposing at least one chip of the chip unit and the at least one dummy die on the first RDL unit; c) forming the encapsulation layer that covers the first RDL unit, the at least one chip and the at least one dummy die; d) forming the second RDL unit on a top side of the encapsulation layer that faces away from the first RDL unit to be electrically connected to the at least one chip; e) removing the substrate to expose a plurality of first RDL connected pads at a bottom side of the first RDL unit and obtaining a semi-finished product; f) obtaining the semiconductor package component by cutting the semi-finished product along an edge line to create the oblique package edge of the semiconductor package component, the edge line corresponding in position to the oblique package edge. In the step b) of disposing the at least one chip of the chip unit and the at least one dummy die on the first RDL unit, the at least one dummy die is disposed to extend in a direction parallel to the edge line (EL) in an area which is close to the edge line (EL), or encompasses the edge line.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view illustrating a conventional semiconductor package component.

FIG. 2 is a schematic top view illustrating an embodiment of a semiconductor package component according to the disclosure.

FIG. 3 is a schematic cross-sectional view taken along line III-III in FIG. 2.

FIGS. 4 to 7 are schematic cross-sectional views showing consecutive process steps in a method of making the embodiment shown in FIG. 2.

FIG. 8 is a schematic top view illustrating another embodiment of the semiconductor package component according to the disclosure.

FIG. 9 is a schematic cross-sectional view taken from line a-a in

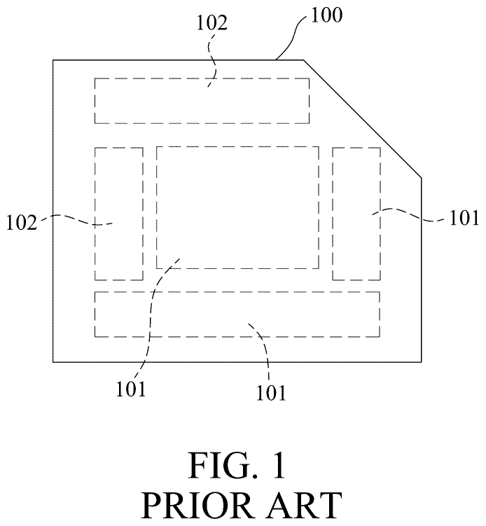

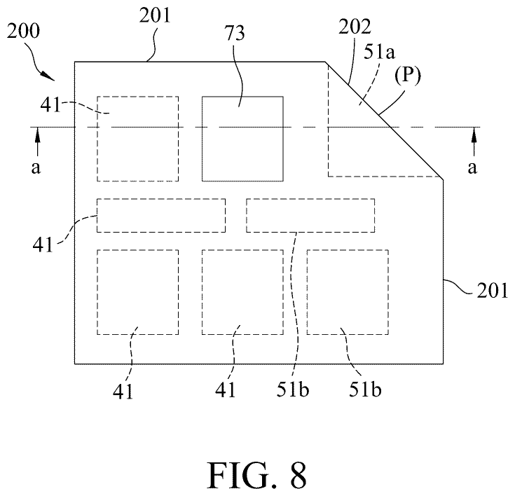

FIG. 8.

FIG. 10 is a schematic top view illustrating a method for making the another embodiment shown in FIG. 8.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

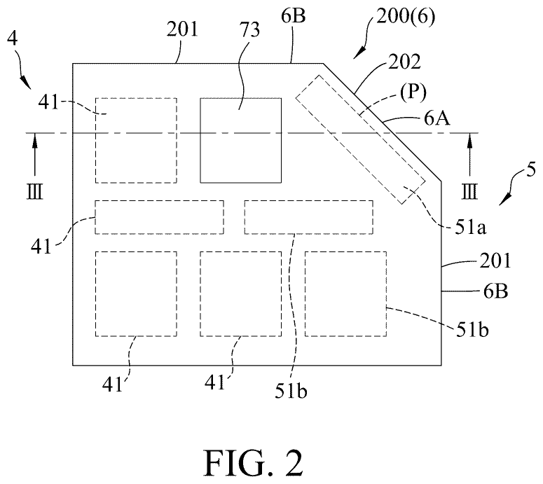

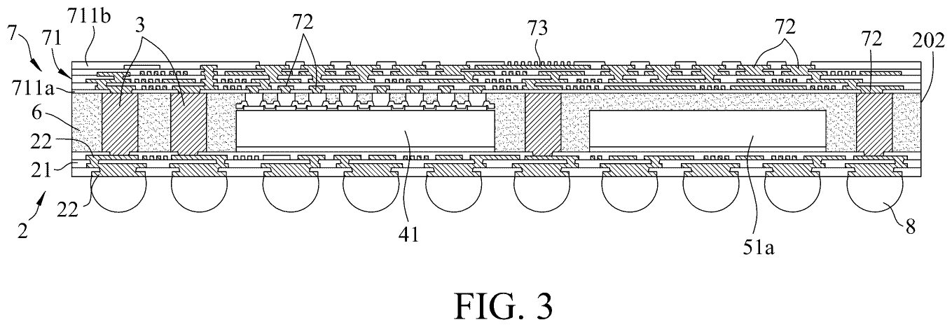

Referring to FIGS. 2 and 3, an embodiment of the present disclosure is a semiconductor package component 200 which is a fan-out package having an outer profile including an oblique package edge 202 obliquely interconnecting between two adjacent side walls 201. In this embodiment, the outer profile of the semiconductor package component 200 looks like a rectangle formed with a chamfered edge, and the oblique package edge 202 is located at the chamfered edge. FIG. 2 is a schematic top view of the semiconductor package component 200, which shows only relative positions of the chip unit 4 and the dummy die unit 5. FIG. 3 is a schematic cross-sectional view taken along line III-III in FIG. 2.

In particular, the semiconductor package component 200 has an outer profile resembling a chamfered rectangle, a first redistribution layer (RDL) unit 2, a plurality of conductive pillars 3, a chip unit 4, a dummy die unit 5, an encapsulation layer 6, a second RDL unit 7, and a plurality of solder balls 8.

The oblique package edge 202 obliquely interconnects between two sidewalls 201 of the multisided package periphery of the semiconductor package component 200. Specifically, the oblique package edge 202 of the semiconductor package component 200 looks like a chamfered edge and adjoins non-perpendicularly each of the two sidewalls 201 of the multisided periphery of the semiconductor package component 200. While the semiconductor package component 200 has only one oblique package edge 202 in this embodiment, the semiconductor package component of the present disclosure is not limited thereto.

In some embodiments, the semiconductor package component 200 may have a shape with more than one oblique package edge, such as a shape of a rectangle with more than one chamfered edge (e.g., two chamfered edges), or a shape of a polygon with more than four oblique package edges or sides.

The first RDL unit 2 has a first RDL structure 21 and a plurality of first RDL connector pads 22 that are disposed on top and bottom sides of the first RDL structure 21 and that are electrically connected to the first RDL structure 21. The first RDL connector pads 22 are for electrical connection to an external electrical circuit.

More specifically, the first RDL structure 21 is composed of a plurality of dielectric layers (not shown) made of an insulating dielectric material alternatingly stacked with a plurality of circuit layers (not shown) made of a conducting material. The first RDL connector pads 22 are exposed from the top and bottom sides of the first RDL structure 21 which are both dielectric layers, and the first RDL connecter pads 22 are electrically connected to the first RDL structure 21. The insulating dielectric material of the dielectric layers may be polyimide (PI). The conducting material of the circuit layers may be Cu, Cu/Ni/Au, Cu/Ni/Sn or Cu/Ni/SnAg etc. Because the structure, material and process of fabricating the first RDL unit 2 are well known in the art, further details are omitted for the sake of brevity.

The conductive pillars 3 are electrically connected to the first RDL structure 21 through the first RDL connector pads 22. In some embodiments, the conductive pillars 3 may be made of copper, or a copper alloy.

In this embodiment, the chip unit 4 has a plurality of chips 41 formed on the first RDL unit 2 and electrically isolated via an insulating adhesive material.

The dummy die unit 5 includes at least one dummy die 51a disposed on the first RDL unit 2, and having a dummy die edge (P) which extends in a direction parallel to the oblique package edge 202 of the semiconductor package component 200. Referring to FIG. 2, in this embodiment, the dummy die unit 5 includes multiple dummy dies 51a, 51b disposed on the first RDL unit 2. The dummy die 51a has a dummy die edge (P) which is a lengthwise side of the dummy die 51a and which is close to and parallel to the oblique package edge 202 of the semiconductor package component 200. It is noted that in this embodiment, the dummy die edge (P) of the dummy die 51a has a length that is proximately equal to the length of the oblique package edge 202. Alternatively, there may be more than one shorter dummy dies 51a which are aligned along the oblique package edge 202 and each of which has a length of the dummy die edge (P) shorter than the length of the oblique package edge 202. In this embodiment, the dummy dies 51b are disposed on the first RDL unit 2 in areas not occupied by the chips 41 of the chip unit 4 so as to cooperate with the chips 41 to form a symmetric arrangement on the first RDL unit 2 and to have even distribution of dummy dies 51a, 51b and chips 41 on the first RDL unit 2. This helps to maintain the symmetry of the semiconductor package component 200 and decrease stress buildup. The dummy dies 51a, 51b are connected to the first RDL unit 2 via the insulating adhesive material.

The encapsulation layer 6 covers the first RDL unit 2, the conductive pillars 3, the chip unit 4, and the dummy die unit 5. The chips 41 of the chip unit 4 has a plurality of connection points that are exposed on the encapsulation layer 6 in a direction opposite to the first RDL unit 2. More specifically, the encapsulating layer 6 has a periphery which surrounds the first RDL unit 2, the chip unit 4, and the dummy die unit 5, and includes an oblique side 6A obliquely interconnecting between other two sides 6B of the periphery. The oblique side 6A of the encapsulating layer 6 corresponds to the oblique package edge 202. The dummy die edge (P) extends in a direction parallel to the oblique side 6A of the encapsulating layer 6.

The second RDL unit 7 is formed on the top side of the encapsulation layer 6, opposite to the first RDL unit 2, and is electrically connected to the chip unit 4. The second RDL unit 7 has a second RDL structure 71, a plurality of second RDL connector pads 72, and a metallic identification code layer 73.

More specifically, the second RDL structure 71 consists of a plurality of dielectric layers (only the outermost dielectric layers 711a and 711b are shown in FIG. 3) which are made of an insulating dielectric material alternatingly stacked with a plurality of circuit layers (not shown) which are made of a conducting material. The second RDL connector pads 72 are exposed on a top surface of the second RDL structure 71 in a direction opposite to the top side of the encapsulation layer 6. The second RDL connector pads 72 allow electrical connection of the chip unit 4 with an external power source. More specifically, the second RDL structure 71 has a top dielectric layer 711b and a bottom dielectric layer 711a that are the outermost layers respectively forming top and bottom surfaces of the second RDL unit 7. Some of the second RDL connector pads 72 are exposed from the top dielectric layer 711b of the second RDL structure 71, and some of the second RDL connector pads 72 are exposed from the bottom dielectric layer 711a of the second RDL structure 71.

The conductive pillars 3 each has two opposite ends that are respectively electrically connected to one of the plurality of the first RDL connector pads 22 disposed at the top side of the first RDL structure 21 that face toward the second RDL unit 7 and one of the plurality of the second RDL connector pads 72 disposed at a bottom surface of the second RDL unit 7. In other words, the second RDL connector pads 72 that are located between the encapsulation layer 6 and the second RDL structure 71 and exposed from the bottom dielectric layer 711a are connected to the conductive pillars 3 and the chips 41 of the chip unit 4. The top dielectric layer 711b at the top surface of the second RDL unit 7 is light-transmissive which means the top dielectric layer 711b may be transparent, semi-transparent, or in some embodiments, the top dielectric layer 711b may be opaque but has a through hole or multiple through holes for the admission of light therethrough. In some embodiments, the top dielectric layer 711b is made of a transparent material such as polyimide (PI). The second RDL connector pads 72 that are remote from the first RDL unit 2 and that are exposed form the top dielectric layer 711b are for electrical connection to an external electrical circuit. The metallic identification code layer 73 is electrically isolated from the second RDL structure 71 and disposed in proximity to the top surface of the second RDL unit 7. The metallic identification code layer 73 is located below the top dielectric layer 711b; or, in other words, the top dielectric layer 711b covers the metallic identification code layer 73. The metallic identification code layer 73 has a recognition pattern that is optically readable. In some embodiments, the recognition pattern of the metallic identification code layer 73 is laser ablated; for example, in some embodiments the recognition pattern may be an optically readable 2D marker. Additionally, the top dielectric layer 711b has a hole that corresponds to the recognition pattern.

The solder balls 8 are formed on a bottom side of the first RDL unit 2 away from the chip unit 4, and are connected to the first RDL unit 2. More specifically the solder balls 8 are formed on the bottom side of the first RDL structure 21 that faces away form the second RDL unit 7, and are respectively electrically connected to the first RDL connector pads 22 exposed at the bottom side of the first RDL structure 21. The solder balls 8 are used for electrical connection to an external electric circuit.

In some embodiments, the semiconductor package component 200 may further include an anti-reflection layer (not shown) located between the metallic identification code layer 73 and the top dielectric layer 711b. The anti-reflection layer may help to reduce reflection so that the readability of the recognition pattern may be improved.

It should be noted that in some embodiments of the semiconductor package component 200, the metallic identification code layer 73 may be omitted according to practical requirements.

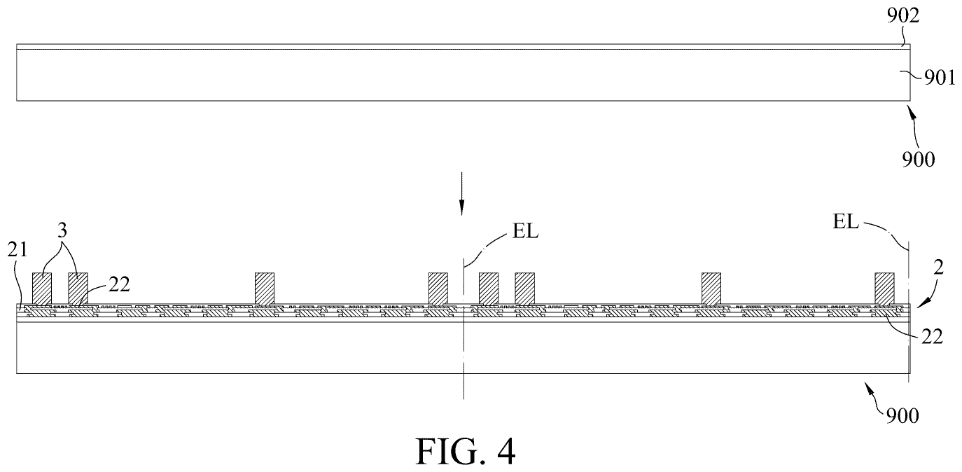

A method of making the semiconductor package component 200 shown in FIG. 2 includes steps a) to f). Referring to FIGS. 3 and 4, in the step a) the first RDL unit 2 is formed on a substrate 900, and a plurality of conductive pillars 3 that are electrically connected to the first RDL unit 2 are formed. The substrate 900 has a base layer 901 and an adhesive layer 902 that is formed on the base layer 901. The adhesive layer 902 is decomposable by heat or light.

More specifically, in step a), photolithography and metal-organic chemical vapor deposition (MOCVD) are conducted to form the first RDL structure 21 that is composed of the dielectric layers (not shown) and the circuit layers (not shown) alternatingly stacked together, the first RDL connector pads 22 that are formed on the first RDL structure 21 and that are exposed from the top side of the first RDL structure 21 that is opposite from the substrate 900, and the conductive pillars 3 that are electrically connected to the first RDL unit 2, and that extends away from the substrate 900.

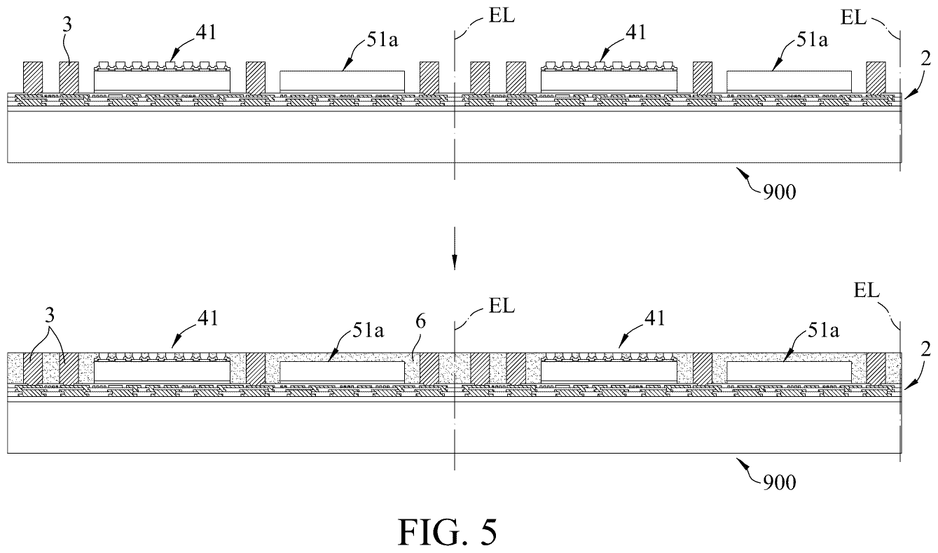

Referring to FIG. 5 in combination with FIGS. 2 and 3, in the step b), at least one chip 41 of the chip unit 4 and at least one dummy die 51a are disposed on the first RDL unit 2. As shown in FIGS. 2 and 3, multiple chips 41 and multiple dummy die 51a, 51b are disposed on the first RDL unit 2 which in turn is disposed on the substrate 900. The chips 41 and the dummy dies 51a, 51b are adhered to the first RDL unit 2 via an insulating adhesive material. The dummy dies 51b and the chips 41 are evenly distributed on the first RDL unit 2 as shown in FIG. 2. The disposing of the dummy die 51a will be detailed hereinafter.

Referring to FIG. 5, in the step c) the encapsulation layer 6 is formed to cover the first RDL unit 2, the chips 4 and the dummy dies 51a, 51b.

More specifically, a liquid encapsulation material such as epoxy is injection molded to cover a surface of the first RDL unit 2, the chips 41, the dummy dies 51a, 51b, and the conductive pillars 3. Subsequently, the encapsulation material is ground and polished until the chips 41, and the conductive pillars 3 are partially exposed thus forming the finished encapsulation layer 6. In some embodiments, the encapsulation layer 6 is formed to embed the conductive pillars 3. Top ends of the conductive pillars 3 are exposed by a grinding process.

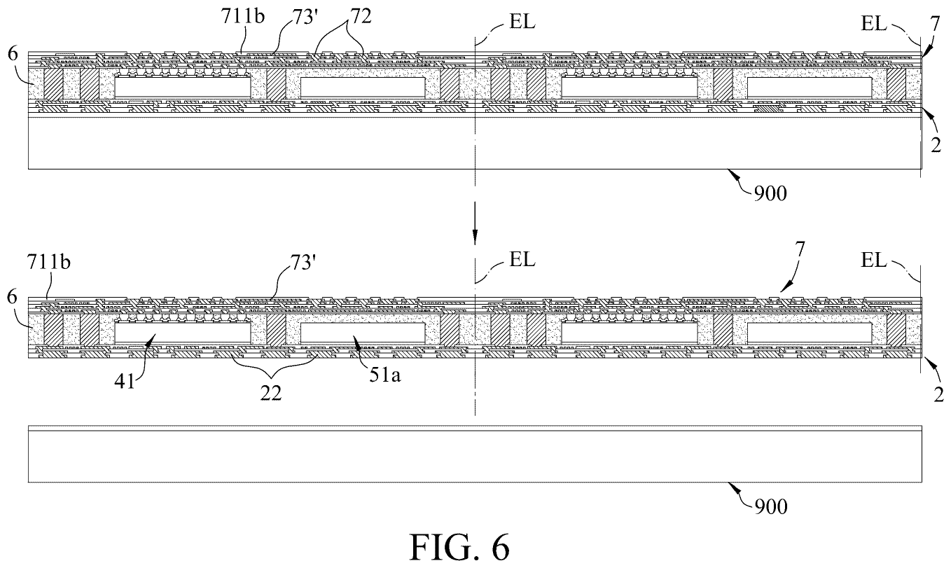

Next, referring to FIG. 6, in the step d) the second RDL unit 7 is formed on a top side of the encapsulation layer 6 that faces oppositely from the first RDL unit 2 to be electrically connected to the chips 41.

More specifically, the second RDL unit 7 is formed on the top side of the encapsulation layer 6 to electrically connect with the top ends of the conductive pillars 3 and the chips 41. The second RDL unit 7 is made in a similar way to the first RDL unit 2; however, the second RDL unit 7 has a top dielectric layer 711b that is an outermost layer of the second RDL unit 7 and is located in proximity to the top surface of the second RDL unit 7 and remote from the first RDL unit 2. The top dielectric layer 711b is light-transmissive which means the top dielectric layer 711b may be transparent, semi-transparent, or in some embodiments, may have a through hole for the admission of light therethrough. In some embodiments, the top dielectric layer 711b is made of a transparent material such as polyimide (PI). Additionally, the second RDL unit 7 has a plurality of second RDL connector pads 72, and a metallic layer 73′ each located in proximity to the top surface of the second RDL unit 7. The second RDL connector pads 72 are exposed from the top dielectric layer 711b for electrical connection to an external circuit, and the metallic layer 73′ is covered by the top dielectric layer 711b. More specifically, the metallic layer 73′ is not electrically connected to the second RDL structure 71, has a size that is larger than any of the second RDL connector pads 72, and is used to form the metallic identification code layer 73.

Referring to FIG. 6, in the step e) the substrate 900 is removed to expose a plurality of the first RDL connector pads 22 at a bottom side of the first RDL unit 2 and a semi-finished product 300 is obtained. The substrate 900 is removed according to the characteristics of the adhesive layer 902. For example, if the adhesive layer 902 is heat-decomposable, the substrate 900 is removed via heating, and if the adhesive layer 902 is photo-decomposable, the substrate 900 is removed via light exposure.

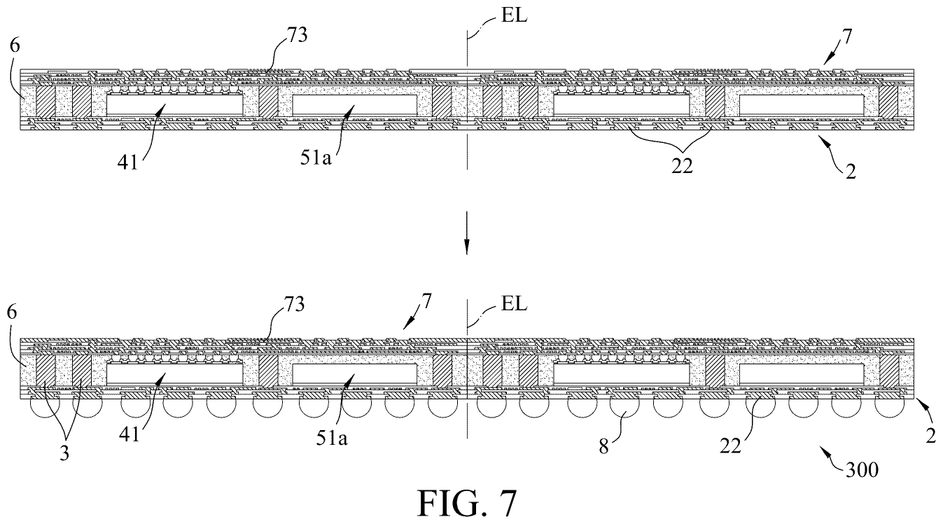

Referring to FIG. 7, in the step e) the obtaining of the semi-finished product 300 includes using a laser to ablate the metallic layer 73′ below the dielectric layer 711b for forming a recognition pattern so that the metallic layer 73′ is formed into a metallic identification code layer 73. In addition, solder balls 8 are respectively formed on the first RDL connector pads 22 exposed at the bottom side of the first RDL unit 2 as shown in FIG. 7. Since laser ablation is a well known technique for a person skilled in the art, further details are omitted for the sake of brevity.

It should be noted that in some embodiments, the recognition pattern may be printed instead of laser ablated. In the case, in the step d), before forming the dielectric layer 711b that is the outermost layer of the second RDL unit 7, the recognition pattern is printed on a top surface of the metallic layer 73′ and the dielectric layer 711b is formed afterwards. The ablating of the metallic layer 73′ in step e) may be skipped and the method may proceed to the forming of the solder balls 8 respectively on the first RDL connector pads 22 exposed at the bottom side of the first RDL unit 2.

Finally, in the step f) the semi-finished product 300 is cut along an edge line (EL) to create the oblique package edge 202 of the semiconductor package component 200. The edge line (EL) corresponds in position to the oblique package edge 202. The semi-finished product 300 is cut along the edge line (EL) while it is diced for singulation.

The disposing of the dummy die 51a is related to the position of the edge line (EL). In step (b), the dummy die 51a is disposed to extend in a direction parallel to the edge line (EL) in an area which is close to the edge line (EL) (see FIGS. 2, 3 and 5), or encompasses the edge line (EL) (see FIGS. 8, 9, 5 and 10).

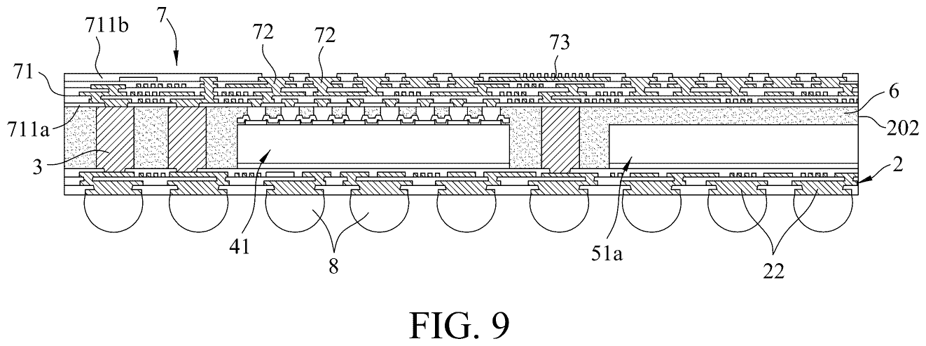

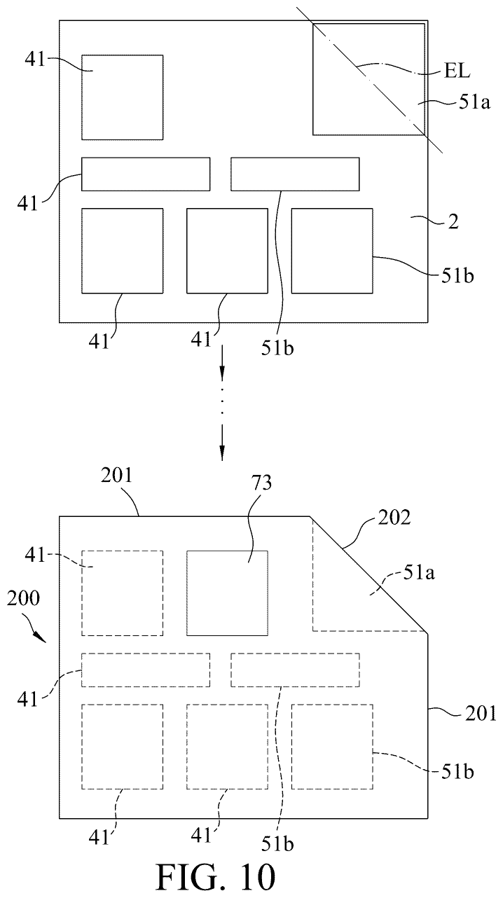

It should be noted that the oblique package edge 202 of the semiconductor package component 200 may have different cross-section configurations according to the way of disposing the dummy die 51a. Referring to FIGS. 2, 3 and 5, the dummy die edge (P) of the dummy die 51a is close to and parallel to the edge line (EL) and is located on one side of the edge line (EL). In this case, the resulting final product will have the dummy die edge (P) of the dummy die 51a being parallel to the oblique package edge 202 and being completely located inside the encapsulation layer 6, as shown in FIG. 2. The dummy die edge (P) is one of two lengthwise sides of the dummy die 51a. However, referring to FIGS. 8 and 9, in another embodiment, the dummy die edge (P) of the dummy die 51a is a cross section of the dummy die 51a exposed from the encapsulating layer 6, and is coplanar to the encapsulating layer 6. Therefore, the oblique package edge 202 of the semiconductor package component 200 is composed of the dummy die 51a and the encapsulation layer 6.

A method for making the another embodiment of the semiconductor package component 200 shown in FIGS. 8 and 9 differs from the previous method illustrated in FIGS. 4 to 7 in terms of disposing the dummy die 51a. Referring to FIG. 10, in this method the dummy die 51a is disposed in an area that encompasses the edge line (EL). Specifically, the area spans across the edge line (EL) and extends on both sides of the edge line (EL) so that the dummy die 51a can be intersected by the edge line (EL). When the semi-finished product 300 is cut along the edge line (EL) in step f), the encapsulation layer 6 and the dummy die 51a are cut at the same time. This results in the dummy die edge (P) of the dummy die 51a being exposed from the encapsulation layer 6 at the oblique package edge 202, as shown in FIG. 9.

Additionally, it should be understood that when the semiconductor package component 200 includes the anti-reflection layer (not shown) located between the metallic identification code layer 73 and the top dielectric layer 711b of the second RDL unit 7, the method of making the semiconductor package component 200 should be slightly modified so that in the step d) of forming the second RDL unit 7, the anti-reflection layer should be formed on the metallic layer 73′ before the top dielectric layer 711b is formed on the anti-reflection layer to cover the anti-reflection layer.

In summary of the above, in the semiconductor package component 200 according to the present disclosure, by virtue of having the dummy die edge (P) of the dummy die 51a extending in a direction parallel to the oblique package edge 202 of the semiconductor package component 200, the structural strength of the semiconductor package component along the oblique package edge 202 may be improved. Additionally, unequal stress buildup due to uneven distribution of chips and dummy dies 51a, 51b because of the asymmetrical shape of the semiconductor package component 200 may be prevented. By preventing unequal stress buildup in the semiconductor package component 200, warpage of the semiconductor package component 200 may be prevented. Furthermore, in the method of making the semiconductor package component 200, a metallic layer 73′ may be formed while the second RDL circuit unit is formed, and the metallic layer 73′ may be laser ablated to form the recognition pattern or to be printed with the recognition pattern. This simplifies the process for making the metallic identification code layer 73 and streamlines the production process. Additionally, the metallic identification code layer 73 is protected by the top dielectric layer 711b. This is in contrast to conventional semiconductor package components where a component analogous to the metallic identification code layer 73 of the disclosure is exposed on an outer surface of the conventional semiconductor package component and is likely to become oxidized due to exposure to ambient environment. This may cause difficulty in reading the recognition pattern.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor package component which has an outer profile including an oblique package edge obliquely interconnecting between two adjacent side walls, said semiconductor packaging component comprising:
a first redistribution layer (RDL) unit;
a chip unit disposed on said first RDL unit;
a dummy die unit including at least one dummy die disposed on said first RDL unit, and having a dummy die edge which extends in a direction parallel to said oblique package edge;
an encapsulation layer covering said first RDL unit, said chip unit, and said dummy die unit;
a second RDL unit formed on a top side of said encapsulation layer that is opposite to said first RDL unit, being electrically connected to said chip unit, and having a plurality of second RDL connector pads that are exposed on a top surface of said second RDL unit facing opposite from said top side of said encapsulation layer, and that allow electrical connection of said chip unit with an external power source.

2. The semiconductor package component as claimed in claim 1, wherein:
said dummy die edge of said at least one dummy die is exposed from said encapsulation layer, and is coplanar to said encapsulation layer; and
said oblique package edge is composed of said dummy die edge and a cross-section of said encapsulation layer, said dummy die edge is a cross section of said at least one dummy die.

3. The semiconductor package component as claimed in claim 1, wherein said dummy die edge of said at least one dummy die is a lengthwise side of said at least one dummy die, is parallel to said oblique package edge and is completely located inside said encapsulation layer.

4. The semiconductor package component as claimed in claim 1, wherein:
said first RDL unit has a first RDL structure and a plurality of first RDL connector pads that are disposed on top and bottom sides of said first RDL structure and that are electrically connected to said first RDL structure;
said semiconductor package component further comprising
a plurality of conductive pillars each having two opposite ends that are respectively electrically connected to one of said plurality of first RDL connector pads disposed at said top side of said first RDL structure that faces toward said second RDL unit and one of said plurality of said second RDL connector pads disposed at a bottom surface of said second RDL structure, and
a plurality of solder balls formed on said bottom side of said first RDL structure that faces away from said second RDL unit, and respectively electrically connected to said first RDL connector pads exposed at said bottom side of said first RDL structure.

5. The semiconductor package component as claimed in claim 1, wherein:
said second RDL unit further having a metallic identification code layer disposed in proximity to said top surface of said second RDL unit, and a top dielectric layer that covers said metallic identification code layer, and that is light-transmissive, said metallic identification code layer having a recognition pattern that is optically readable.

6. The semiconductor package component as claimed in claim 5, wherein:
said recognition pattern of said metallic identification code layer is laser ablated; and
said top dielectric layer has a hole that corresponds to said recognition pattern.

7. The semiconductor package component as claimed in claim 5, further comprising an anti-reflection layer located between said metallic identification code layer and said top dielectric layer.

8. The semiconductor package component as claimed in claim 1, further comprising a plurality of solder balls formed on a bottom side of said first RDL unit away from said chip unit, and being electrically connected to said first RDL unit.

9. The semiconductor package component as claimed in claim 1, wherein:
said encapsulating layer has a periphery which surrounds said first RDL unit, said chip unit and said dummy unit, and which includes an oblique side obliquely interconnecting between other two sides of said periphery, said oblique side of said encapsulating layer corresponding to said oblique package edge, said dummy side edge extending in a direction parallel to said oblique side of said encapsulating layer.

10. A method of making the semiconductor package component of claim 1, comprising:
a) forming the first RDL unit on a substrate;
b) disposing at least one chip of the chip unit and the at least one dummy die on the first RDL unit;
c) forming the encapsulation layer that covers the first RDL unit, the at least one chip and the at least one dummy die;
d) forming the second RDL unit on a top side of the encapsulation layer that faces away from the first RDL unit to be electrically connected to the at least one chip;
e) removing the substrate to expose a plurality of first RDL connector pads at a bottom side of the first RDL unit and obtaining a semi-finished product;
f) cutting the semi-finished product along an edge line to create the oblique package edge of the semiconductor package component, the edge line corresponding in position to the oblique package edge;
wherein in the step (b) of disposing at least one chip of the chip unit and the at least one dummy die on the first RDL unit, the at least one dummy die is disposed to extend in a direction parallel to the edge line in an area which is close to the edge line, or encompasses the edge line.

11. The method of making the semiconductor package component as claimed in claim 10, wherein:
the second RDL unit has a top dielectric layer that is made of a transparent material, a plurality of second RDL connector pads, and a metallic layer each located in proximity to a top surface of the second RDL unit, the second RDL connector pads are exposed from the top dielectric layer, and the metallic layer is covered by the top dielectric layer; and
In the step (e), the obtaining of the semi-finished product includes using a laser to ablate the metallic layer below the dielectric layer for forming a recognition pattern so that the metallic layer is formed into a metallic identification code layer.

12. The method of making the semiconductor package component as claimed in claim 10, wherein in the step e), the obtaining of the semi-finished product further includes forming solder balls respectively on the first RDL connector pads exposed at the bottom side of the first RDL unit.

13. The method of making the semiconductor package component as claimed in claim 10, wherein:
the step a) further includes forming a plurality of conductive pillars that are electrically connected to the first RDL unit, and that extend away from the substrate;
in the step c) of forming the encapsulation layer, the encapsulation layer is formed to embed the conductive pillars and top ends of the conductive pillars exposed by a grinding process; and
in the step d) of forming the second RDL unit, the second RDL unit is formed to electrically connect with the top ends of the conductive pillars.

14. The method of making the semiconductor package component as claimed in claim 10, wherein the at least one dummy die is disposed in the area which is close to the edge line on one side of the edge line.

15. The method of making the semiconductor package component as claimed in claim 10, wherein the at least one dummy die is disposed in the area which spans across the edge line and extends on both sides of the edge line.
